(19) United States
(12) Patent Application Publication
(10) Pub. No.: US 2006/0280967 A1
(43) Pub. Date: Dec. 14, 2006

(54) Organic electroluminescent element

(75) Inventor: Hiroshi Tada, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/451,562

(22) Filed: Jun. 13, 2006

(30) Foreign Application Priority Data
Jun. 14, 2005 (JP) 2005-174064

(51) Int. Cl. H01L 51/50; H05B 33/12

(52) U.S. Cl. 428/690; 428/917; 428/212; 313/504; 313/506; 257/E51.05; 257/E51.043

(57) ABSTRACT

The invention provides an organic electroluminescent element having a cathode, an electron injection promoting layer, a luminescent layer and an anode in that order, wherein the luminescent layer is adjacent to the electron injection promoting layer and contains a luminescent material, and the electron injection promoting layer contains an electron transport material and has a thickness of 3 nm or less, and the electron affinity of the electron transport material is equal to or higher than the electron affinity of the luminescent material.

### CROSS-REFERENCE TO RELATED APPLICATION

This application claims priority under 35 USC 119 from Japanese Patent Application No. 2005-174064, the disclosure of which is incorporated by reference herein.

### BACKGROUND OF THE INVENTION

1. Field of the Invention

The invention relates to an organic electroluminescent element (hereinafter also referred to as an “organic EL element”, “luminescent element” or “EL element”) that can convert electrical energy to light to produce luminescence.

2. Description of the Related Art

In recent years, research and development regarding various display elements have been actively conducted. Specifically, organic electrical field luminescence (EL) elements are drawing attention as potential display elements for producing high-intensity luminescence at low voltages.

Organic electroluminescent elements have electrodes (anode and cathode) facing each other, and, between the electrodes, a luminescent layer or a plurality of organic layers containing a luminescent layer. In the luminescent layer, electrons injected from the cathode recombine with holes injected from the anode to generate excitons. The excitons produce luminescence by themselves, or energy transfers therefrom to other molecules to change these molecules into excitons, which produce luminescence.

An organic electroluminescent element further having an electron transfer controlling layer for controlling electron flow to the luminescent layer and therefore having improved efficiency and service life has been disclosed (for example, see Japanese Patent Application Laid-Open (JP-A) No. 2004-273163).

Organic electroluminescent elements further having a hole blocking layer for blocking leakage of holes and therefore having improved luminescence efficiency have also been disclosed (for example, see JP-A Nos. 2000-243571 and 2000-3790).

However, none of these organic electroluminescent elements have sufficient luminescence efficiency and durability, and the improvements in their properties are demanded.

Accordingly, organic electroluminescent elements that are superior both in luminescence characteristics and driving durability are demanded.

### SUMMARY OF THE INVENTION

The invention has been made in view of the above circumstances and provides an organic electroluminescent element having a cathode, an electron injection promoting layer, a luminescent layer and an anode in that order, wherein the luminescent layer is adjacent to the electron injection promoting layer and contains a luminescent material, and the electron injection promoting layer contains an electron transport material and has a thickness of 3 nm or less, and the electron affinity of the electron transport material is equal to or higher than the electron affinity of the luminescent material.

### DETAILED DESCRIPTION OF THE INVENTION

Organic Electroluminescent Element

The organic electroluminescent element of the invention (hereinafter referred to as an “organic EL element” in some cases) will be described in detail below.

The organic electroluminescent element of the invention has a cathode, an electron injection promoting layer, a luminescent layer, and an anode in that order. The luminescent layer is adjacent to the electron injection promoting layer and contains at least one luminescent material. The electron injection promoting layer contains at least one electron transport material and has a thickness of 3 nm or less. The electron affinity of each of the at least one electron transport material is equal to or higher than the electron affinity of each of the at least one luminescent material.

The organic electroluminescent element of the invention has improved luminescence efficiency and excellent driving durability because of the above structure.

The reasons why the luminescent element of the invention has excellent driving durability and luminescence characteristics (luminescence efficiency) are thought to be as follows.

The electron transport material(s) contained in the electron injection promoting layer in the invention enhances the injection of electrons into the luminescent layer, and thereby has the function of improving carrier balance and luminescence efficiency in the luminescent layer. The electron transport material having electron affinity equal to or higher than that of the luminescent material promotes the injection of electrons to improve luminescence efficiency. However, when the electron injection promoting layer is thick, holes are injected into the electron transport material, which causes the material to readily decompose. In general, a thick layer including an electron transport material and adjacent to the luminescent layer serves as a hole blocking layer, and blocks leak of holes from the luminescent layer to improve luminescence efficiency. However, the holes are injected into the electron transport material, which causes the material to readily decompose. Accordingly, an element having such a thick layer has poor durability. This is because electron transport materials generally have low resistance to the injection of holes.

In the invention, the electron injection promoting layer has a thickness of 3 nm or less, which prevents decomposition of the electron transport material to improve element durability. This is because the electron injection promoting layer is strictly a discontinuous (islands-like) film rather than a continuous film, and holes are not readily injected into the electron transport material. More specifically, since the electron injection promoting layer is a discontinuous film, holes leaking from the luminescent layer do not enter the electron injection promoting layer. Even if the holes enter the electron injection promoting layer, the holes pass through the electron injection promoting layer toward a layer adjacent to the electron injection promoting layer without remaining in the electron injection promoting layer, which prevents the electron transport material from deteriorating.

The thickness in the invention refers to an average thickness. In producing an element, a desired thickness of a layer made of each material is set as follows. A monolayer film that is made of each material and is practically slightly uneven, and therefore has thicknesses of 50 to 200 nm is formed on a substrate having a known thickness. The thicknesses of the resultant laminate are measured with a step height measuring device or an optical film thickness measuring device, and the calculated thicknesses are averaged. The thickness of the monolayer film is calculated from the average thickness of the laminate and the thickness of the substrate, and a desired thickness of a layer made of the material is set on the basis of the calculated thickness.

When a phosphorescent material is used as the luminescent material in the invention, an especially high effect is obtained. In principle, the luminescence efficiency of the phosphorescent element is four times as high as that of a fluorescent element. Accordingly, use of phosphorescent material is an important technique for improving efficiency. Since the life of excitons in the phosphorescent element is long, disruption of carrier balance in the luminescent layer significantly affects luminescence efficiency. Here, the invention can improve the carrier balance.

The electron affinity of a material is calculated from the band gap and the ionization potential (IP) of the material in the invention. Here, the band gap is obtained by forming a monolayer film of the material, measuring the absorption spectrum of the monolayer film, and calculating the band gap from the absorption peak having the longest wavelength.

The ionization potential is a value measured with an ultraviolet photoelectron analyser (AC-1 manufactured by Riken Keiki Co., Ltd.) at room temperature at atmospheric pressure. The measurement principle of analyser AC-1 is described in “Yukihakumaku Shigotokansu Datashu (Data Book of Work Function of Organic Thin Film)” written by Chihaya Adachi et al. and published by CMC Inc. in 2004.

For materials having an ionization potential of higher than 6.2 eV, a USP (vacuum ultraviolet photoelectron spectroscopy) method is used in view of the measurement range.

The structure of the organic electroluminescent element of the invention will be described below.

The luminescent element of the invention has a pair of electrodes [i.e., cathode (negative electrode) and anode (positive electrode)], and a luminescent layer between the electrodes, and an electron injection promoting layer adjacent to the cathode side of the luminescent layer. Each of the cathode and the anode is preferably formed on or above a substrate. The element may have at least one organic compound layer other than the luminescent layer and the electron injection promoting layer, between the luminescent layer and the anode, and/or between the electron injection promoting layer and the cathode. At least one of the anode and the cathode is preferably transparent so as to allow the element to serve as a luminescent element. In general, the anode is transparent.

The organic electroluminescent element of the invention preferably has a structure in which an anode, a hole transport layer, a luminescent layer, an electron injection promoting layer and a cathode are laminated in that order. Moreover, the organic electroluminescent element may have an electric charge blocking layer between the hole transport layer and the luminescent layer.

In the invention, each of the layers between the pair of electrodes, which layers include the luminescent layer, is generically referred to as an “organic compound layer”.

The components of the organic electroluminescent layer of the invention will be described in detail below.

Substrate

It is preferable that the material of the substrate used in the invention does not scatter or attenuate light emitted by the luminescent layer. Specific examples thereof include inorganic materials such as yttrium-stabilized zirconia (YSZ), and glass; and organic materials such as polyesters including polyethylene terephthalate, polybutylene phthalate, and polyethylene naphthalate, polystyrene, polycarbonate, polyether sulphone, polyallylate, polyimide, polycycloolefin, norbornene resins, and poly(chlorotrifluoroethylene).

When the substrate is made of, for example, glass, it is preferable to use a non-alkali glass as the glass in order to reduce ions seeping from the glass. When soda lime glass is used as the substrate material, the substrate preferably has a barrier coat made of, for example, silica. When the substrate is made of an organic material, the material preferably has excellent heat resistance, dimensional stability, solvent resistance, electrical insulating property and processability.

The shape, structure, and size of the substrate are not particularly limited and can be selected appropriately in accordance with the intended use and purpose of the luminescent element. In general, the substrate is preferably plate-shaped. The structure of the substrate may be either a monolayer structure or a laminated structure. Further, the substrate may be made of a single material or of two or more materials.

The substrate may be colorless and transparent, or colored and transparent, but is preferably colorless and transparent. This is because such a substrate does not scatter or attenuate light emitted by the luminescent layer.

A moisture permeation-preventing layer (gas barrier layer) may be provided on the front surface or the back surface of the substrate.

The moisture permeation-preventing layer (gas barrier layer) is preferably made of at least one of inorganic substances such as silicon nitride and silicon oxide. The moisture permeation-preventing layer (gas barrier layer) can be formed by, for example, radiofrequency sputtering.

When the substrate is made of a thermoplastic material, at least one of a hard coat layer and an undercoat layer may be provided on the substrate.

Anode

The anode functions as an electrode that supplies holes to the organic compound layer(s), and the shape, the structure, and the size thereof are not particularly limited. The material of the anode can be appropriately selected from known electrode materials according to the intended use and purpose of the luminescent element. As described above, the anode is usually transparent.

The anode may be made of a metal, an alloy, a metal oxide, an electrically conductive compound or a mixture thereof. The anode preferably has a work function of 4.0 eV or greater. Specific examples of the material of the anode include electrically conductive metal oxides such as tin oxide into which antimony or fluorine is doped (ATO, or FTO), tin oxide, zinc oxide, indium oxide, indium tin oxide (ITO), and indium zinc oxide (IZO); metals such as gold, silver, chromium, and nickel; mixtures and laminates of at least one of those metals and at least one of those electrically conductive metal oxides; electrically conductive inorganic materials such as copper iodide, and copper sulfide; electrically conductive organic materials such as polyaniline, polythiophene, and polypyrrole; and laminates of ITO and at least one of these substances. Among these, the material of the anode is preferably an electrically conductive metal oxide, and, from the viewpoints of productivity, high electrical conductivity and transparency, is more preferably ITO.

The anode can be formed on the substrate by a wet method such as printing or coating, a physical method such as vacuum deposition, sputtering or ion plating, or a chemical method such as CVD or plasma CVD. The method for forming the anode is appropriately selected in consideration of suitability of the method to the material of the anode. When the material of the anode is, for example, ITO, formation of the anode can be carried out by DC sputtering, radiofrequency sputtering, vacuum deposition, or ion plating.

The organic electroluminescent element of the invention can have the anode in any position. The position of the anode in the organic electroluminescent element can be selected according to the intended use and purpose of the element. It is preferable that the anode is formed on the substrate. In this case, the anode may be formed on the entire surface of one side of the substrate, or in a part of the one side.

Moreover, patterning in forming the anode may be carried out by chemical etching such as etching using photolithography, physical etching such as etching with a laser, vacuum deposition or sputtering using a mask, a lift-off method, or a printing method.

The thickness of the anode can be appropriately selected in accordance with the type of the material of the anode and thus cannot be clearly defined. However, the thickness is usually from 10 nm to 50 μm, and preferably from 50 nm to 20 μm.

The resistance value of the anode is preferably 10³ Ω/sq. or less, and more preferably 10² Ω/sq. or less. When the anode is transparent, the anode may be colorless or colored. In order to obtain luminescence from the transparent anode side, the transmittance of the anode is preferably 60% or higher, and more preferably 70% or higher.

The detail of transparent anodes is described in “Tohmeidenkyokumaku No Shintenkai (New Development of Transparent Electrode Films)” supervised by Yutaka Sawada and published by CMC Inc. in 1999, the descriptions of which are applicable to the invention. When the substrate is made of a plastic having low heat resistance, it is preferable that the anode is ITO or IZO and is formed at a low temperature of 150° C. or below.

Cathode

The cathode functions as an electrode that injects electrons to the organic compound layer(s). There is no limitation on the shape, the structure, and the size of the cathode. The material of the cathode can be appropriately selected from known electrode materials according to the intended use and purpose of the luminescent element.

The cathode may be made of a metal, an alloy, a metal oxide, an electrically conductive compound or a mixture thereof. The cathode preferably has a work function of 4.5 eV or less. Specific examples of the material of the cathode include alkali metals (e.g., Li, Na, K, and Cs), alkaline earth metals (e.g., Mg, and Ca), gold, silver, lead, aluminum, sodium-potassium alloy, lithium-aluminum alloy, magnesium-silver alloy, rare earth metals such as indium, and ytterbium. The cathode may be made of one of these materials, but, from the viewpoints of achieving both stability and electron injection property, is preferably made of two or more of these materials.

Among these, the cathode is preferably made of at least one of alkali metals and alkaline earth metals from the viewpoint of electron injection property, and is more preferably made of a material mainly containing aluminum from the viewpoint of excellent storage stability.

Examples of the material mainly containing aluminum include aluminum itself, and alloys and mixtures including aluminum and 0.01 to 10% by mass of at least one alkali metal or at least one alkaline earth metal (e.g., lithium-aluminum alloy, and magnesium-aluminum alloy).

In addition, the detail of the materials of cathodes is described in JP-A Nos. H02-15595 and H05-121172, and the materials described therein are applicable to the invention.

A method for forming the cathode is not particularly limited and may be selected from known methods. The cathode can be formed by a wet method such as printing or coating, a physical method such as vacuum deposition, sputtering or ion plating, or a chemical method such as CVD or plasma CVD. The method for forming the cathode is appropriately selected in consideration of suitability of the method to the material of the cathode. When the cathode is made of, for example, at least one metal, the cathode can be formed by sputtering the metal, or by simultaneously or successively sputtering the metals.

Patterning in forming the cathode may be carried out by chemical etching such as etching using photolithography, physical etching such as etching with a laser, vacuum deposition or sputtering using a mask, a lift-off method, or a printing method.

The organic electroluminescent element of the invention can have the cathode in any position. The cathode may be formed on the entire surface of one side of one or more of the organic compound layers, or in a part of the one side.

Further, the organic luminescent element of the invention may have a dielectric layer made of fluoride or oxide of an alkali metal or an alkaline earth metal and having a thickness of 0.1 to 5 nm between the cathode and one of the organic compound layers. The dielectric layer can be regarded as a kind of an electron-injecting layer. The dielectric layer can be formed by, for example, vacuum deposition, sputtering, or ion plating.

The thickness of the cathode can be appropriately selected in accordance with the type of the material of the cathode and thus cannot be clearly defined. The thickness is usually from 10 nm to 5 μm, and preferably from 50 nm to 1 μm.

The cathode may be transparent or opaque. A transparent cathode can be formed by forming a film made of a cathode material and having a thickness of 1 to 10 nm and laminating thereon a transparent electrically conductive material such as ITO or IZO.

Organic Compound Layer

The organic electroluminescent element of the invention may have any other layer(s) as well as the luminescent layer and the electron injection promoting layer adjacent to the cathode side of the luminescent layer.

Other layer(s) may be at least one of a hole transport layer, an electron transport layer, an electric charge-blocking layer, a hole-injecting layer and an electron-injecting layer.

The details of these layers will be described later.

Formation of Organic Compound Layers

Each of the organic compound layers in the organic electroluminescent element of the invention can be suitably formed by any method selected from dry film forming methods such as vapor deposition and sputtering, a transfer method, and a printing method.

—Luminescent Layer—

The luminescent layer receives holes from the anode, the hole-injecting layer or the hole transport layer and electrons from the cathode, the electron-injecting layer or the electron transport layer, and provides a place where the holes are recombined with the electrons to produce luminescence, when an electrical field is applied to the organic electroluminescent element.

The luminescent layer in the invention contains at least one luminescent material, and preferably contains at least one host material and the at least one luminescent material(s) serving as a dopant. The luminescent material is preferably a phosphorescent material.

The type of the host material is not particularly limited, and the host material is preferably an electric charge transport material.

The organic luminescent element may have one or at least two luminescent layers.

The phosphorescent material contained in the luminescent layer is generally a complex including at least one transition metal atom or lanthanoid atom.

The type of the transition metal atom is not particularly limited. However, the transition metal atom is preferably ruthenium, rhodium, palladium, tungsten, rhenium, osmium, iridium or platinum, and more preferably rhenium, iridium or platinum.

Examples of the lanthanoid atom include lanthanum, cerium, praseodymium, neodymium, samarium, europium, gadolinium, terbium, dysprosium, holmium, erbium, thulium, ytterbium and lutetium. Among these lanthanoid atoms, at least one of neodymium, europium and gadolinium is preferred.

Examples of the ligands of the complex include those described in “Comprehensive Coordination Chemistry” written by G. Wilkinson et al. and published by Pergamon Press in 1987, those described in “Photochemistry and Photophysics of Coordination Compounds” written by H. Yersin and published by Springer-Verlag in 1987, and those described in “Yukikinzoku Kagaku-Kiso To Oyo (Organometal Chemistry—Foundation and Application)” written by Akio Yamamoto and published by Shokabo in 1982.

Specifically, the ligand is preferably a halogen ligand (preferably a chlorine ligand), a nitrogen-containing heterocyclic ligand (e.g., phenyl pyridine, benzoquinoline, quinolinol, bipyridyl, or phenanthroline), a diketone ligand (e.g., acetylacetone), a carboxylic acid ligand (e.g., an acetic acid ligand), a carbon monoxide ligand, an isonitrile ligand, or a cyano ligand, and more preferably a nitrogen-containing heterocyclic ligand. The complex may have only one transition metal atom, and may also be a so-called polynuclear complex having two or more transition metal atoms. The complex may contain different kinds of metal atoms.

The content of the phosphorescent material(s) in the luminescent layer is preferably from 0.1 to 20% by mass, and more preferably from 0.5 to 10% by mass.

The type of the host material contained in the luminescent layer in the invention is not particularly limited. Examples of the host material(s) contained in the luminescent layer in the invention include compounds having a carbazole skeleton, compounds having a diarylamine skeleton, compounds having a pyridine skeleton, compounds having a pyrazine skeleton, compounds having a triazine skeleton and compounds having a arylsilane skeleton. Among them, the host material is preferably a compound having a carbazole skeleton.

The T1 level (the energy level of the lowest multiplet excited state) of each of the at least one host material is preferably greater than the T1 level of each of the at least one dopant. A luminescent layer in which the dopant(s) is doped in the host material(s) can be appropriately formed by co-depositing the host material(s) and the dopant(s).

The thickness of the luminescent layer is not particularly limited, but is preferably from 1 nm to 500 nm, more preferably from 5 nm to 200 nm, and even more preferably from 10 nm to 100 nm.

The content of the host material(s) in the luminescent layer is preferably from 50 to 99.9% by mass, and more preferably from 70 to 99.9% by mass.

—Electron Injection Promoting Layer—

The electron injection promoting layer has the function of promoting the injection of electrons to the luminescent layer through the cathode side of the luminescent layer. In the invention, the electron injection promoting layer is provided as an organic compound layer adjacent to the cathode side of the luminescent layer.

It is necessary that the electron affinity of each of the at least one electron transport material contained in the electron injection promoting layer be equal to or higher than the electron affinity of each of the at least one luminescent material. When the luminescent layer contains at least one host material, the electron affinity of each of the at least one electron transport material is preferably equal to or higher than the electron affinity of each of the at least one host material in order to efficiently inject electrons into the luminescent layer.

The electron affinity of each of the at least one electron transport material is preferably 2.7 eV or higher, more preferably 2.7 eV to 4.1 eV, still more preferably 2.9 eV to 3.9 eV, and most preferably 3.2 eV to 3.9 eV.

It is necessary that the electron injection promoting layer has a thickness of 3 nm or less. The thickness is preferably 0.1 to 2 nm, more preferably 0.1 nm to 1 nm, and still more preferably 0.2 to 0.8 nm.

The electron transport material preferably contains 3 or more nitrogen atoms.

Examples of such an electron transport material include azoles such as oxazole, oxadiazole, imidazole, triazole, thiazole, thiadiazole and derivatives (including condensates) thereof, azines such as pyridine, pyrimidine, triazine and derivatives (including condensates) thereof, organic silanes such as silole, silane having at least one aryl group substituent and derivatives (including condensates) thereof, aromatic hydrocarbon rings having at least one fluoride substituent, and various metal complexes including 8-quinolinol metal complexes, metal phthalocyanine and metal complexes containing at least one benzoxazole or benzothiazole ligand and derivatives thereof.

The electron transport material used in the invention is preferably an azole compound or an azine compound, and more preferably a compound represented by the following formula (A-1) or (B-1).

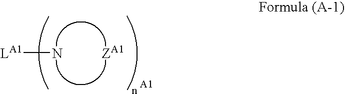

In formula (A-1), Z^{A1} represents an atomic group required for formation of a nitrogen-containing heterocyclic group. L^{A1} represents a linking group. n^{A1} represents an integer of 2 or more.

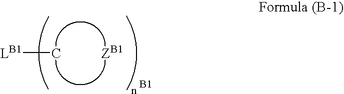

In formula (B-1), Z^{B1} represents an atomic group required for formation of an aromatic hydrocarbon ring or a heterocyclic group. L^{B1} represents a linking group. n^{B1} represents an integer of 2 or more.

The compound represented by formula (A-1) will be described below.

L^{A1} in the formula (A-1) represents a linking group. The linking group represented by L^{A1} is preferably a single bond or a linking group including at least one of carbon, silicon, nitrogen, phosphorus, sulfur, oxygen, boron, and germanium atoms, more preferably a single bond, a carbon atom, a silicon atom, a boron atom, an oxygen atom, a sulfur atom, a germanium atom, an aromatic hydrocarbon ring or an aromatic heterocyclic group, still more preferably a carbon atom, a silicon atom, an aromatic hydrocarbon ring or an aromatic heterocyclic group, still more preferably a polyvalent aromatic hydrocarbon ring, a plyvalent aromatic heterocyclic group or a carbon atom, still more preferably a polyvalent aromatic hydrocarbon ring or a polyvalent aromatic heterocyclic group, and most preferably a 1,3,5-benzenetriyl group, a 1,2,5,6-benzenetetrayl group, a 1,2,3,4,5,6-benzenehexayl group, a 2,2′-dimethyl-4,4′-biphenylene group, a 2,4,6-pyridinetriyl group, a 2,3,4,5,6-pyridinepentayl group, a 2,4,6-pyrimidinetriyl group, a 2,4,6-triazinetriyl group or a 2,3,4,5-thiophenetetrayl group. Specific examples of the linking group represented by L^{A1} include the following groups.

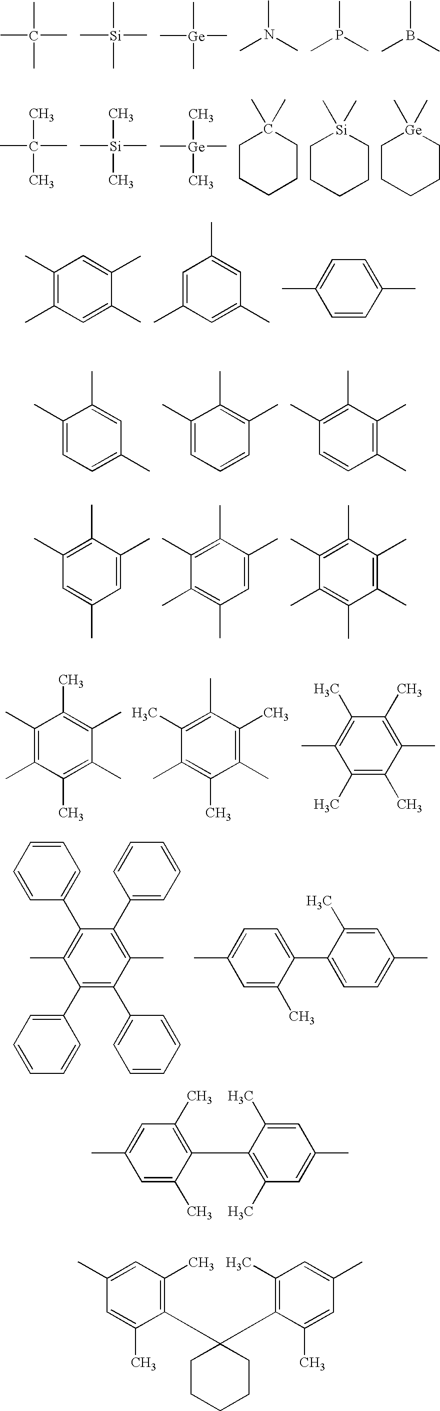

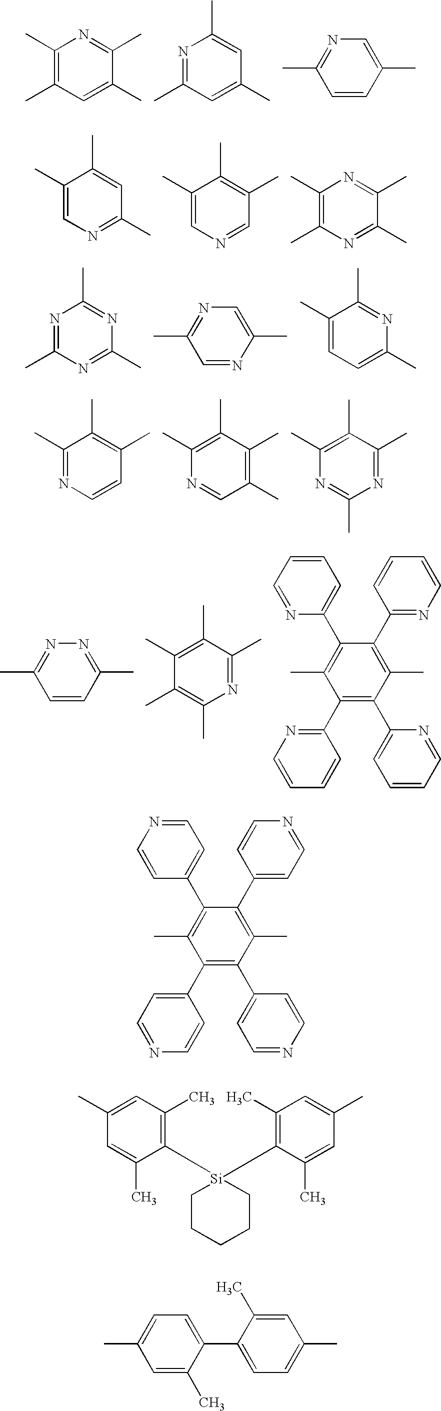

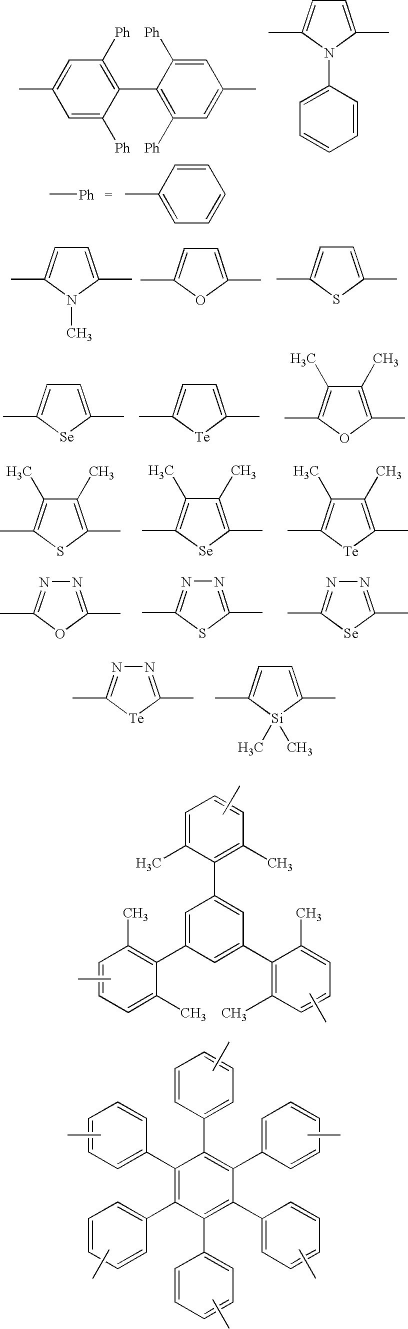

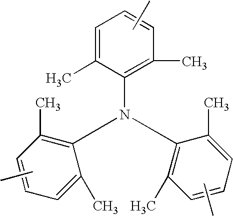

L^{A1} may have at least one substituent. Examples of the substituent include alkyl groups (those preferably having 1 to 30 carbon atoms, more preferably 1 to 20 carbon atoms, and still more preferably 1 to 10 carbon atoms, such as methyl, ethyl, iso-propyl, tert-butyl, n-octyl, n-decyl, n-hexadecyl, cyclopropyl, cyclopentyl and cyclohexyl groups), alkenyl groups (those preferably having 2 to 30 carbon atoms, more preferably 2 to 20 carbon atoms, and still more preferably 2 to 10 carbon atoms, such as vinyl, allyl, 2-butenyl and 3-pentenyl groups), alkynyl groups (those preferably having 2 to 30 carbon atoms, more preferably 2 to 20 carbon atoms, and still more preferably 2 to 10 carbon atoms, such as propargyl and 3-pentynyl groups), aryl groups (those preferably having 6 to 30 carbon atoms, more preferably 6 to 20 carbon atoms, and still more preferably 6 to 12 carbon atoms, such as phenyl, p-methylphenyl, naphthyl and anthranyl groups), amino groups (those preferably having 0 to 30 carbon atoms, more preferably 0 to 20 carbon atoms, and still more preferably 0 to 10 carbon atoms, such as amino, methylamino, dimethylamino, diethylamino, dibenzylamino, diphenylamino and ditolylamino groups), alkoxy groups (those preferably having 1 to 30 carbon atoms, more preferably 1 to 20 carbon atoms, and still more preferably 1 to 10 carbon atoms, such as methoxy, ethoxy, butoxy and 2-ethylhexyloxy groups), aryloxy groups (those preferably having 6 to 30 carbon atoms, more preferably 6 to 20 carbon atoms, and still more preferably 6 to 12 carbon atoms, such as phenyloxy, 1-naphthyloxy and 2-naphthyloxy groups), heterocyclic oxy groups (those preferably having 1 to 30 carbon atoms, more preferably 1 to 20 carbon atoms, and still more preferably 1 to 12 carbon atoms, such as pyridyloxy, pyrazyloxy, pyrimidyloxy and quinolyloxy groups), acyl groups (those preferably having 1 to 30 carbon atoms, more preferably 1 to 20 carbon atoms, and still more preferably 1 to 12 carbon atoms, such as acetyl, benzoyl, formyl and pivaloyl groups), alkoxycarbonyl groups (those preferably having 2 to 30 carbon atoms, more preferably 2 to 20 carbon atoms, and still more preferably 2 to 12 carbon atoms, such as methoxycarbonyl and ethoxycarbonyl groups), aryloxycarbonyl groups (those preferably having 7 to 30 carbon atoms, more preferably 7 to 20 carbon atoms, and still more preferably 7 to 12 carbon atoms, such as a phenyloxycarbonyl group), acyloxy groups (those preferably having 2 to 30 carbon atoms, more preferably 2 to 20 carbon atoms, and still more preferably 2 to 10 carbon atoms, such as acetoxy and benzoyloxy groups), acylamino groups (those preferably having 2 to 30 carbon atoms, more preferably 2 to 20 carbon atoms, and still more preferably 2 to 10 carbon atoms, such as acetylamino and benzoylamino groups), alkoxycarbonylamino groups (those preferably having 2 to 30 carbon atoms, more preferably 2 to 20 carbon atoms, and still more preferably 2 to 12 carbon atoms, such as a methoxycarbonylamino group), aryloxycarbonylamino groups (those preferably having 7 to 30 carbon atoms, more preferably 7 to 20 carbon atoms, and still more preferably 7 to 12 carbon atoms, such as a phenyloxycarbonylamino group), sulfonylamino groups (those preferably having 1 to 30 carbon atoms, more preferably 1 to 20 carbon atoms, and still more preferably 1 to 12 carbon atoms, such as methanesulfonylamino and benzenesulfonylamino groups), sulfamoyl groups (those preferably having 0 to 30 carbon atoms, more preferably 0 to 20 carbon atoms, and still more preferably 0 to 12 carbon atoms, such as sulfamoyl, methylsulfamoyl, dimethylsulfamoyl and phenylsulfamoyl groups), carbamoyl groups (those preferably having 1 to 30 carbon atoms, more preferably 1 to 20 carbon atoms, and still more preferably 1 to 12 carbon atoms, such as carbamoyl, methylcarbamoyl, diethylcarbamoyl and phenylcarbamoyl groups), alkylthio groups (those preferably having 1 to 30 carbon atoms, more preferably 1 to 20 carbon atoms, and still more preferably 1 to 12 carbon atoms, such as methylthio and ethylthio groups), arylthio groups (those preferably having 6 to 30 carbon atoms, more preferably 6 to 20 carbon atoms, and still more preferably 6 to 12 carbon atoms, such as a phenylthio group), heterocyclic thio groups (those preferably having 1 to 30 carbon atoms, more preferably 1 to 20 carbon atoms, and still more preferably 1 to 12 carbon atoms, such as pyridylthio, 2-benzimidazolylthio, 2-benzoxazolylthio and 2-benzthiazolylthio groups), sulfonyl groups (those preferably having 1 to 30 carbon atoms, more preferably 1 to 20 carbon atoms, and still more preferably 1 to 12 carbon atoms, such as mesyl and tosyl groups), sulfinyl groups (those preferably having 1 to 30 carbon atoms, more preferably 1 to 20 carbon atoms, and still more preferably 1 to 12 carbon atoms, such as methanesulfinyl and benzenesulfinyl groups), ureido groups (those preferably having 1 to 30 carbon atoms, more preferably 1 to 20 carbon atoms, and still more preferably 1 to 12 carbon atoms, such as ureido, methylureido and phenylureido groups), phosphoric acid amide groups (those preferably having 1 to 30 carbon atoms, more preferably 1 to 20 carbon atoms, and still more preferably 1 to 12 carbon atoms, such as diethylphosphoric acid amide and phenylphosphoric acid amide groups), a hydroxy group, a mercapto group, halogen atoms (such as a fluorine atom, a chlorine atom, a bromine atom and an iodine atom), a cyano group, a sulfo group, a carboxyl group, a nitro group, a hydroxamic group, a sulfino group, a hydrazino group, an imino group, heterocyclic groups (those preferably having 1 to 30 carbon atoms, and more preferably 1 to 12 carbon atoms and having at least one hetero atom such as a nitrogen atom, an oxygen atom or a sulfur atom, and specific examples thereof including imidazolyl, pyridyl, quinolyl, furyl, thienyl, piperidyl, morpholino, benzoxazolyl, benzimidazolyl, benzthiazolyl, carbazolyl and azepinyl groups), silyl groups (those preferably having 3 to 40 carbon atoms, more preferably 3 to 30 carbon atoms, and still more preferably 3 to 24 carbon atoms, such as trimethylsilyl and triphenylsilyl groups), silyloxy groups (those preferably having 3 to 40 carbon atoms, more preferably 3 to 30 carbon atoms, and still more preferably 3 to 24 carbon atoms, such as trimethylsilyloxy and triphenylsilyloxy groups).

These substituents may have at least one substituent. The substituent is preferably an alkyl group, an aryl group, a heterocyclic group, a halogen atom or a silyl group, more preferably an alkyl group, an aryl group, a heterocyclic group or a halogen atom, and still more preferably an alkyl group, an aryl group, an aromatic heterocyclic group or a fluorine atom.

In formula (A-1), Z^{A1} represents an atomic group required for formation of a nitrogen-containing heterocyclic group, and the nitrogen-containing heterocyclic group containing Z^{A1} may be a single ring or a condensed ring containing two or more rings. The nitrogen-containing heterocyclic group containing Z^{A1} is preferably a 5 to 8-membered nitrogen-containing heterocyclic group, more preferably a 5 to 7-membered nitrogen-containing heterocyclic group, still more preferably a 5 or 6-membered nitrogen-containing aromatic heterocyclic group, and most preferably a 5-membered aromatic heterocyclic group. Nitrogen-containing heterocyclic groups each of which contains Z^{A1} and is linked to L^{A1} may be identical or different.

Specifically, the nitrogen-containing heterocyclic group containing Z^{A1} may be a pyrrole ring, an indole ring, an oxazole ring, an oxadiazole ring, a thiazole ring, aa thiadiazole ring, an azaindole ring, a carbazole ring, a carboline ring (norharman ring), an imidazole ring, a benzimidazole ring, an imidazopyridine ring, a purine ring, a pyrazole ring, an indazole ring, an azaindazole ring, a triazole ring, a tetrazole ring, an azepine ring, an iminostilbene ring (dibenzoazepine ring), a tribenzoazepine ring, a phenothiazine ring or a phenoxazine ring, and is preferably an oxadiazole ring, a triazole ring, an imidazole ring, a benzimidazole ring or an imidazopyridine ring, and more preferably a benzimidazole ring or an imidazopyridine ring.

If possible, Z^{A1}, together with any other ring(s), may form a condensed ring. In addition, Z^{A1} may have at least one substituent. Examples and preferred examples of the substituent that Z^{A1} may have are the same as those of the substituent that L^{A1} in formula (A-1) may have.

n^{A1} represents an integer of 2 or more, and is preferably 2 to 8, and more preferably 2 to 6.

The compound represented by formula (B-1) will be described below.

L^{B1} in formula (B-1) represents a linking group. Examples of the linking group represented by L^{B1} are the same as those of the linking group L^{A1} in formula (A-1). L^{B1} is preferably a single bond, a polyvalent aromatic hydrocarbon ring, a polyvalent aromatic heterocyclic group, a carbon atom, a nitrogen atom or a silicon atom, more preferably a polyvalent aromatic hydrocarbon ring or a polyvalent aromatic heterocyclic group, and still more preferably a 1,3,5-benzenetriyl group, a 1,2,5,6-benzenetetrayl group, a 1,2,3,4,5,6-benzenehexayl group, a 2,2′-dimethyl-4,4′-biphenylene group, a 2,4,6-pyridinetriyl group, a 2,3,4,5,6-pyridinepentayl group, a 2,4,6-pyrimidinetriyl group, a 2,4,6-triazinetriyl group, a 2,3,4,5-thiophenetetrayl group, a carbon atom, a nitrogen atom or a silicon atom.

L^{B1} may have at least one substituent. Examples and preferred examples of the substituent that L^{B1} may have are the same as those of the substituent that L^{A1} in formula (A-1) may have.

Z^{B1} represents an atomic group required for formation of an aromatic hydrocarbon ring or an aromatic heterocyclic ring. The aromatic hydrocarbon ring or aromatic heterocyclic ring containing Z^{B1} may be a single ring or a condensed ring containing two or more rings. The aromatic hydrocarbon rings and the aromatic heterocyclic rings may be identical or different.

The aromatic hydrocarbon ring containing Z^{B1} has preferably 6 to 30 carbon atoms, more preferably 6 to 20 carbon atoms, and still more preferably 6 to 12 carbon atoms. Examples thereof include a benzene ring, a naphthalene ring, an anthracene ring, a phenanthrene ring, a pyrene ring and a triphenylene ring. Among them, the aromatic hydrocarbon ring is preferably a benzene ring, a naphthalene ring, a phenanthrene ring or a triphenylene ring.

The aromatic heterocyclic ring containing Z^{B1} is a single heterocyclic ring or a condensed heterocyclic ring containing two or more rings, and preferably has 1 to 20 carbon atoms, more preferably 2 to 12 carbon atoms, and still more preferably 2 to 10 carbon atoms. The aromatic heterocyclic ring preferably contains at least one of nitrogen, oxygen and sulfur atoms.

Specific examples of the heterocyclic ring containing Z^{B1} include a pyridine ring, a quinoline ring, an isoquinoline ring, an acridine ring, a phenanthridine ring, a pteridine ring, a pyrazine ring, a quinoxaline ring, a pyrimidine ring, a quinazoline ring, a pyridazine ring, a cinnoline ring, a phthalazine ring, triazine ring, an oxazole ring, a benzoxazole ring, a thiazole ring, a benzothiazole ring, an imidazole ring, a benzimidazole ring, a pyrazole ring, an indazole ring, an isoxazole ring, a benzisoxazole ring, an isothiazole ring, a benzisothiazole ring, an oxadiazole ring, a thiadiazole ring, a triazole ring, a tetrazole ring, a furan ring, a benzfuran ring, a thiophene ring, a benzthiophene ring, a pyrrole ring, an indole ring, an imidazopyridine ring, a carbazole ring and a phenanthroline ring. Among these, the heterocyclic group containing Z^{B1} is preferably a pyridine ring, a quinoline ring, an isoquinoline ring, an acridine ring, a phenanthridine ring, a pyrazine ring, a quinoxaline ring, a pyrimidine ring, a quinazoline ring, a pyridazine ring, a phthalazine ring, a triazine ring, an imidazole ring, a benzimidazole ring, a pyrazole ring, an indazole ring, an oxadiazole ring, a triazole ring, an imidazopyridine ring, a carbazole ring or a phenanthroline ring, more preferably a pyridine ring, a quinoline ring, an isoquinoline ring, a pyrazine ring, a quinoxaline ring, a pyrimidine ring, a quinazoline ring, a pyridazine ring, a phthalazine ring, a triazine ring, an imidazole ring, a benzimidazole ring, an oxadiazole ring, a triazole ring, an imidazopyridine ring or a phenanthroline ring, still more preferably a benzimidazole ring, an oxadiazole ring, a triazole ring, an imidazopyridine ring or a phenanthroline ring, and most preferably a benzimidazole ring or an imidazopyridine ring.

The aromatic hydrocarbon ring or aromatic heterocyclic ring containing Z^{B1}, together with any other ring(s), may form a condensed ring. In addition, the aromatic hydrocarbon ring or aromatic heterocyclic ring containing Z^{B1} may have at least one substituent. Examples and preferred examples of the substitute that Z^{B1} may have are the same as those of the substituent that L^{A1} in formula (A-1) may have.

n^{B1} represents an integer of 2 or more, and is preferably 2 to 8, and more preferably 2 to 6.

In the invention, each of the compounds represented by formulae (A-1) and (B-1) may be a low molecular weight compound, an oligomer compound, or a polymer compound whose weight-average molecular weight (polystyrene conversion) is preferably 1,000 to 5,000,000, more preferably 2,000 to 1,000,000, and still more preferably 3,000 to 100,000, and is preferably a low molecular weight compound.

Specific examples of the compounds represented by formulae (A-1) and (B-1) in the invention are shown below, but the invention is not limited by these compounds.

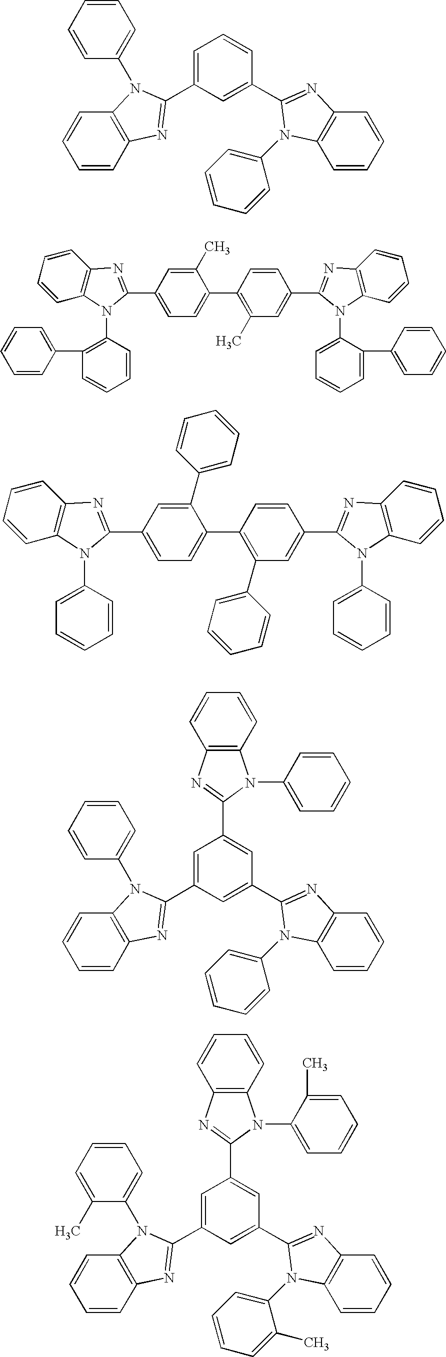

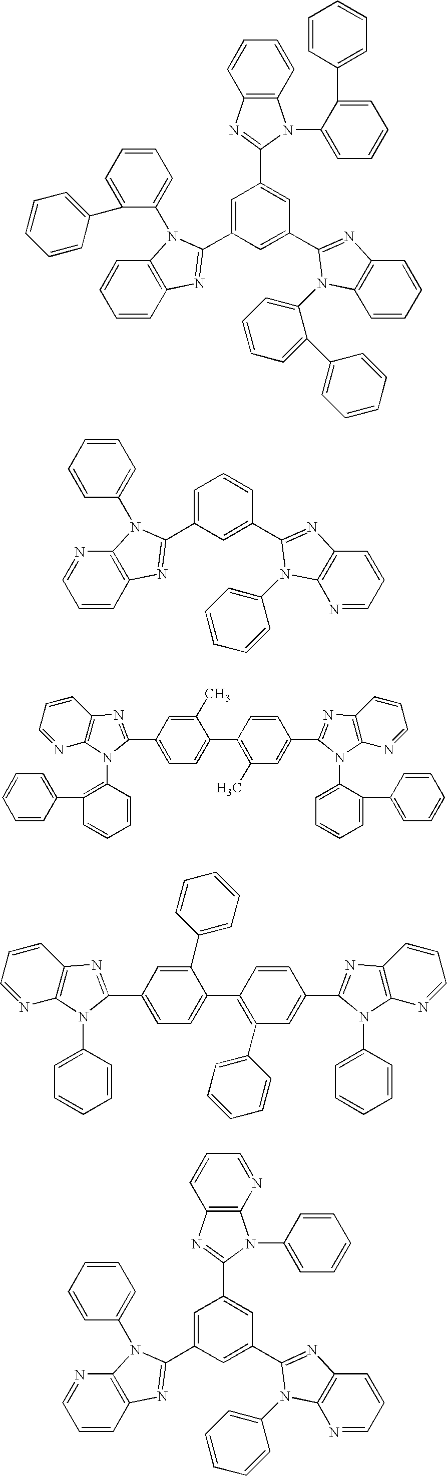

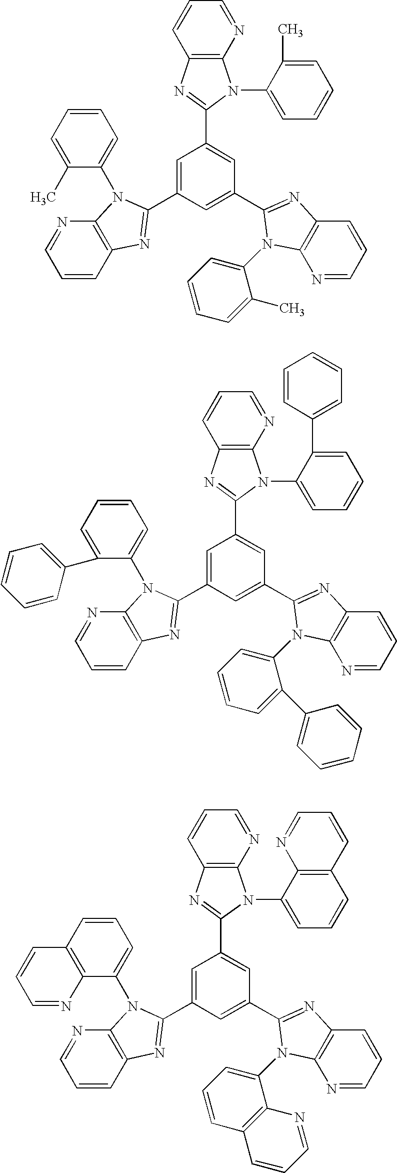

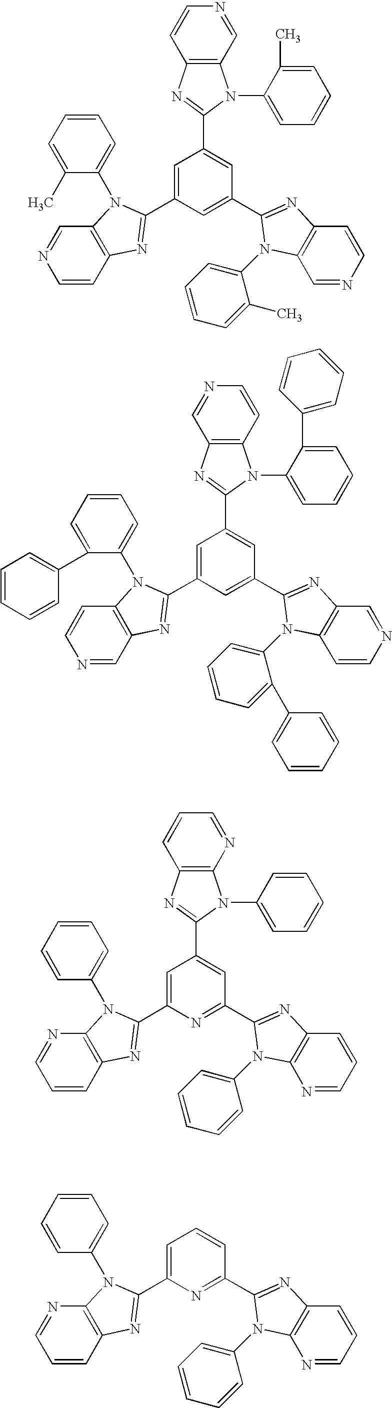

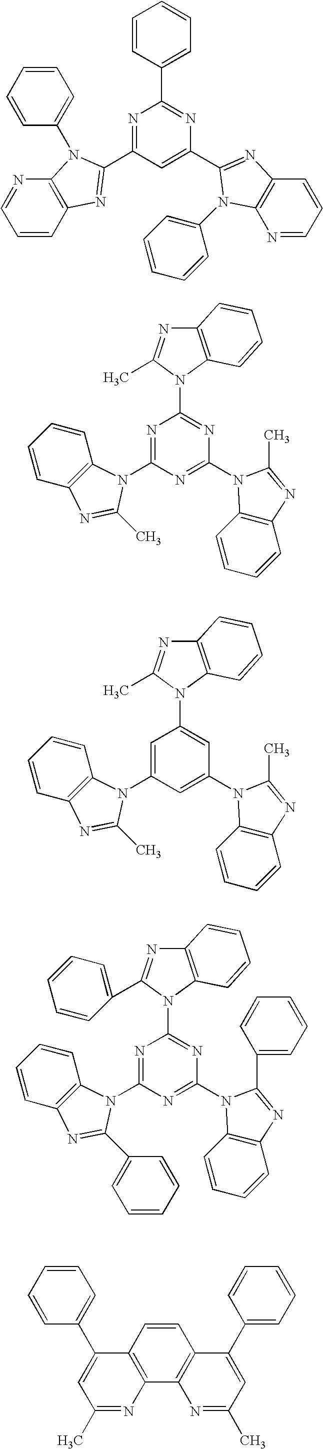

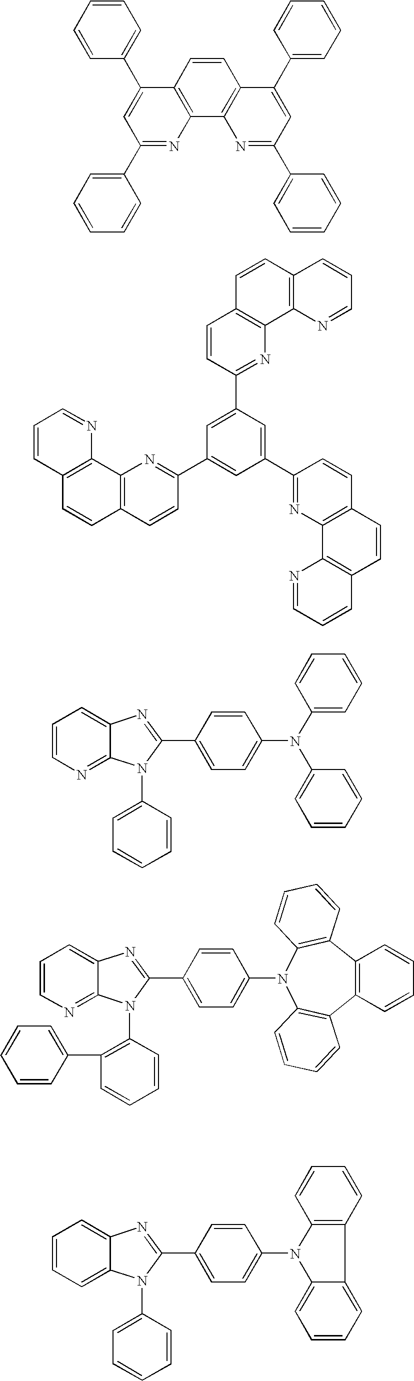

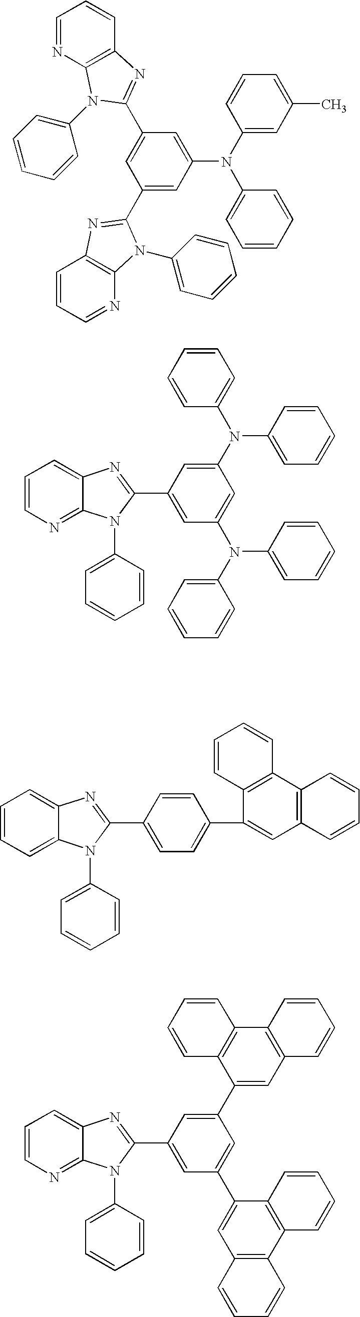

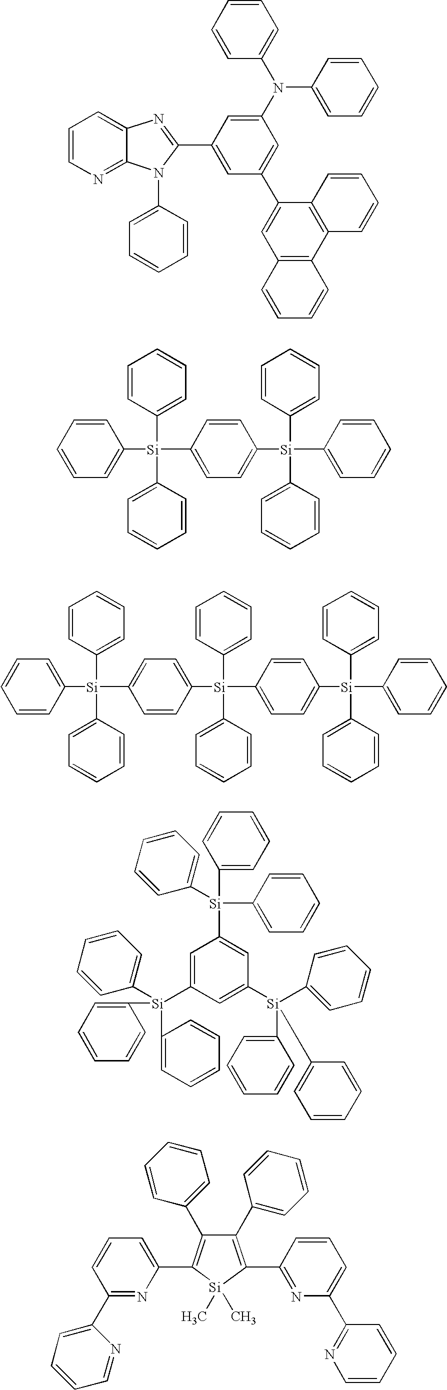

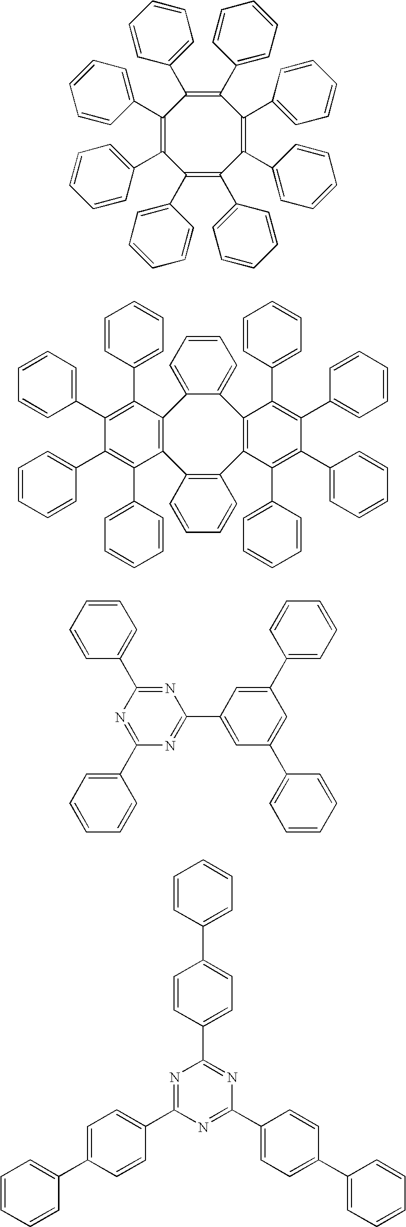

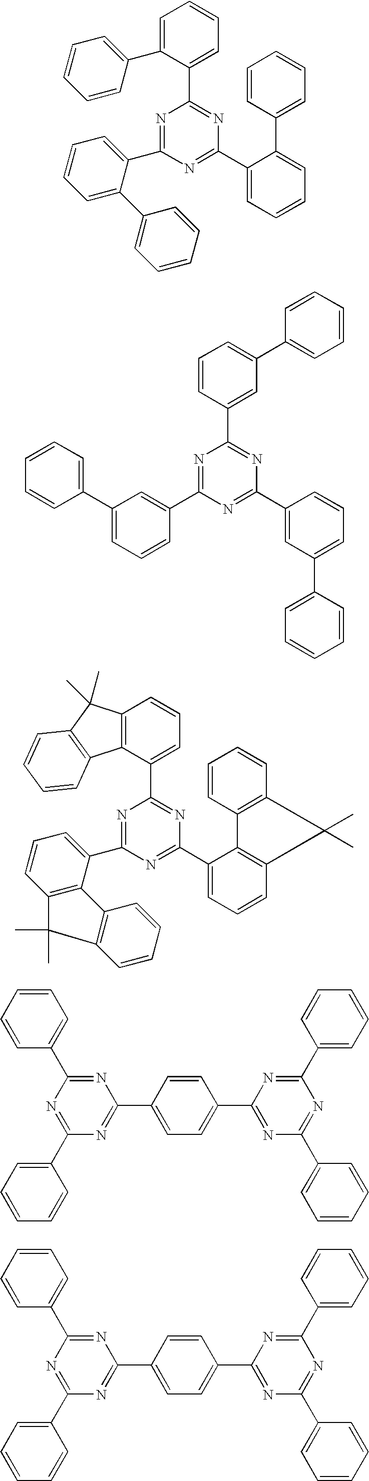

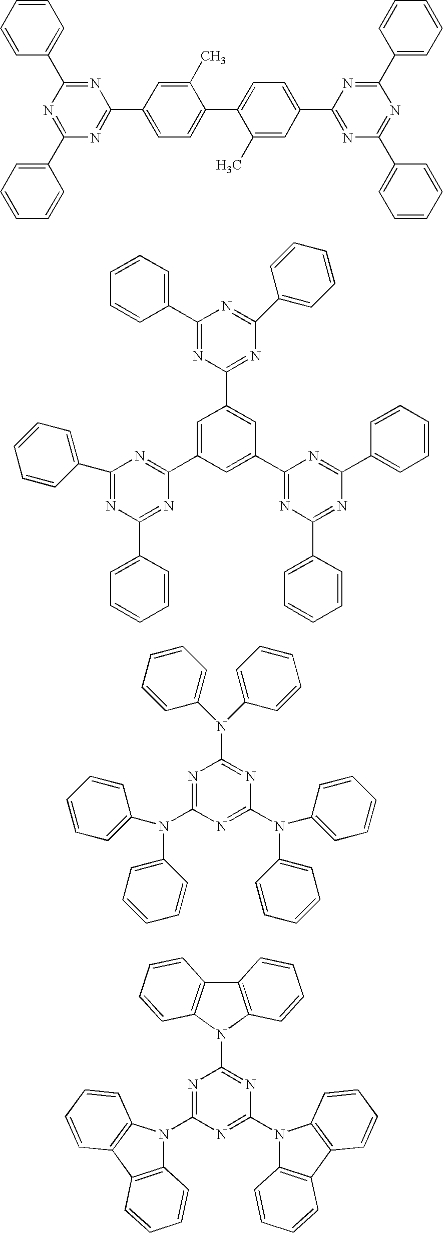

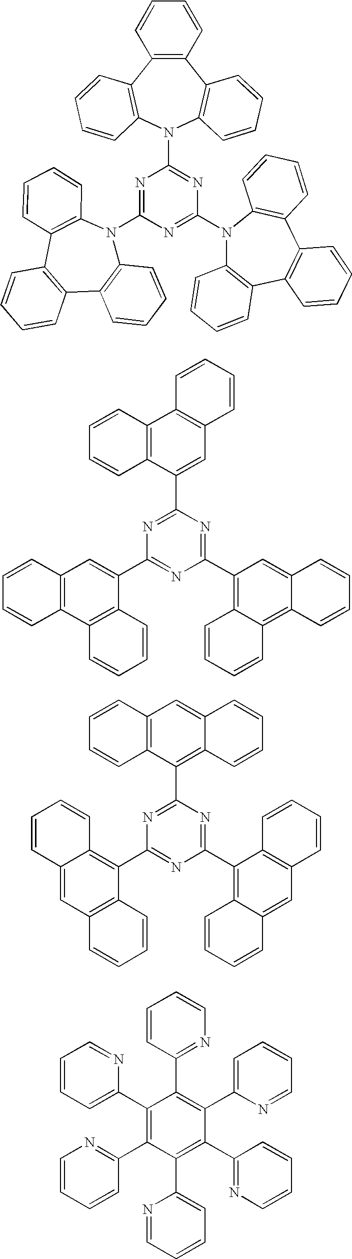

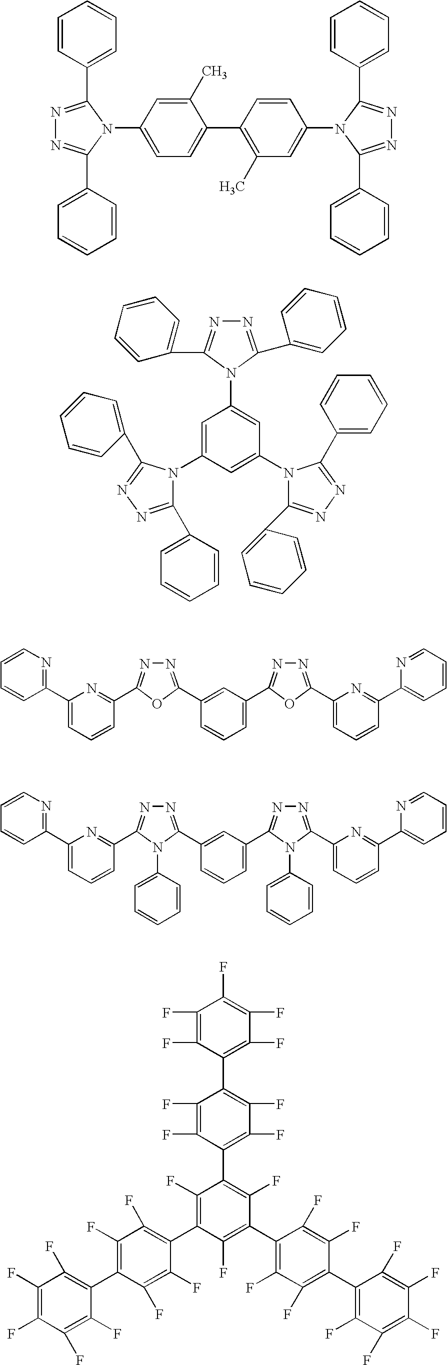

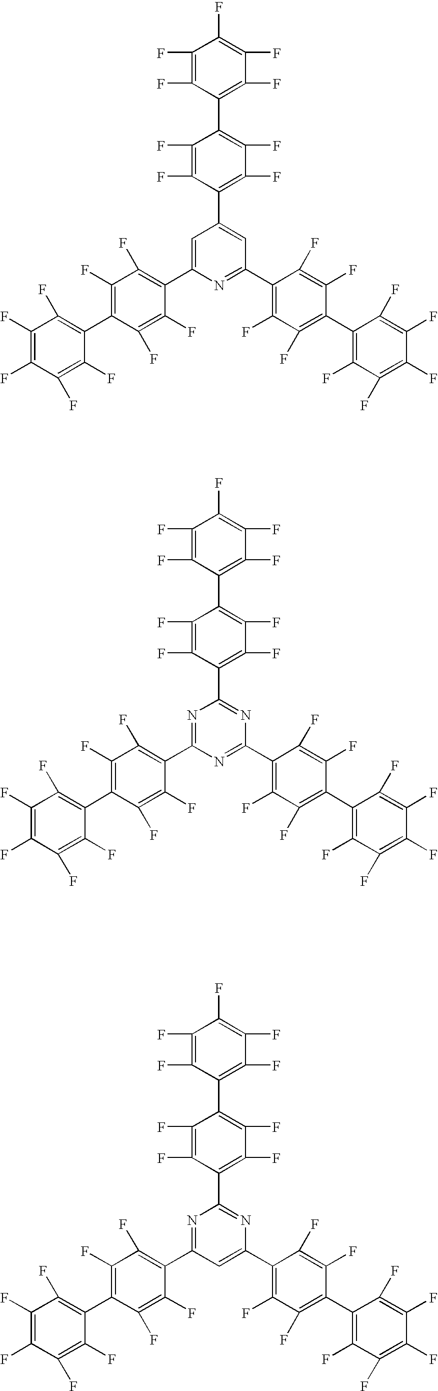

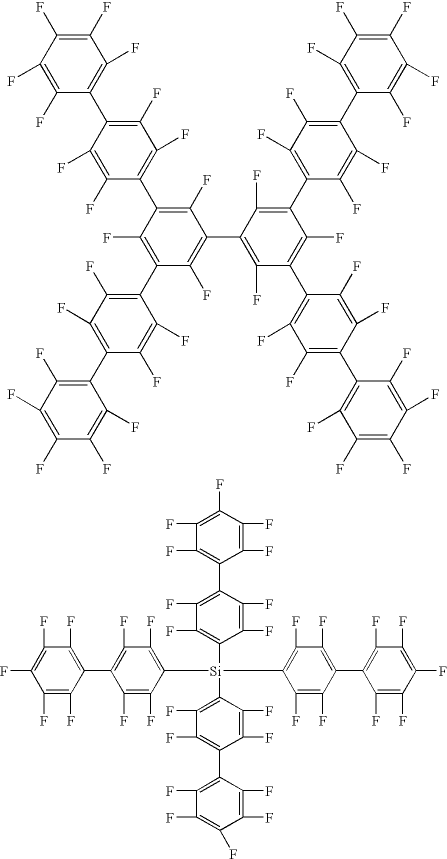

The electron injection promoting layer in the invention may include only one electron transport material or at least two electron transport materials.

It is preferable that the electron injection promoting layer in the invention contains at least one electron transport material and no other material. However, the electron injection promoting layer may contain any other material.

The content of the electron transport material(s) in the electron injection promoting layer is preferably from 50 to 100% by mass, more preferably from 70 to 100% by mass, still more preferably from 80 to 100% by mass, and most preferably 100% by mass.

—Hole-Injecting Layer and Hole Transport Layer—

A hole-injecting layer and a hole transport layer have the function of receiving holes from the anode or a layer adjacent to the anode side of the hole-injecting layer or the hole transport layer and transporting the holes to a layer adjacent to the cathode side of the hole-injecting layer or the hole transport layer. The transport of holes can be promoted by providing the hole transport layer on the anode side of the luminescent layer. Moreover, the injection of holes from the anode can be promoted by providing the hole-injecting layer on the anode side of the hole transport layer.

Each of the hole-injecting layer and the hole transport layer preferably contains at least one of carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene compounds, porphyrin compounds, organic silane derivatives, and carbon.

The thickness of each of the hole-injecting layer and the hole transport layer is preferably 50 nm or less in order to lower the driving voltage of the element.

The thickness of the hole transport layer is more preferably from 5 to 50 nm, and still more preferably from 10 to 40 nm. The thickness of the hole-injecting layer is more preferably from 0.5 to 50 nm, and still more preferably from 1 to 40 nm.

Each of the hole-injecting layer and the hole transport layer may have a single-layered structure including at least one of the aforementioned materials, or a multilayered structure composed of layers having the same composition or different compositions.

—Electron-Injecting Layer and Electron Transport Layer—

An electron-injecting layer and an electron transport layer have the function of receiving electrons from the cathode or a layer adjacent to the cathode side of the electron-injecting layer or the electron transport layer and transporting the electrons to a layer adjacent to the anode side of the electron-injecting layer or the electron transport layer. The transport of electrons can be promoted by providing the electron transport layer on the cathode side of the luminescent layer. Moreover, the injection of electrons from the cathode can be promoted by providing the electron-injecting layer on the cathode side of the electron transport layer.

Each of the electron-injecting layer and the electron transport layer preferably contains at least one of triazole derivatives, oxazole derivatives, oxadiazole derivatives, imidazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, aromatic tetracarboxylic acid anhydrides such as naphthalene and perylene, phthalocyanine derivatives, metal complexes including metal complexes of 8-quinolinol derivatives, metal phthalocyanines, and metal complexes having at least one benzoxazole or benzothiazole ligand, and oganic silane derivatives.

The thickness of each of the electron-injecting layer and the electron transport layer is preferably 50 nm or less in order to lower the driving voltage of the element.

The thickness of each of the electron transport layer and the electron transport layer is more preferably from 5 to 50 nm, and still more preferably 10 to 50 nm.

Each of the electron-injecting layer and the electron transport layer may have a single-layered structure containing one or more of the aforementioned materials, or a multilayered structure composed of layers having the same composition or different compositions.

It is preferable to provide an electron transport layer containing a compound represented by the following formula (C) and adjacent to the cathode side of the electron injection promoting layer.

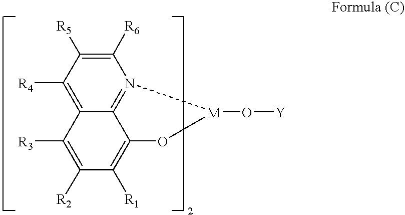

In formula (C), at least one of R₁ to R₆ represents a substitute, and the remaining represents a hydrogen atom. M represents aluminum, gallium or indium. Y represents an aromatic group or silyl group that may have at least one substituent.

The silyl group represented by Y is preferably an alkyl silyl group (an alkyl silyl group preferably having 3 to 40 carbon atoms, more preferably 3 to 30 carbon atoms, and still more preferably 3 to 24 carbon atoms, such as trimethylsilyl and dimethyl-tert-butylsilyl groups), an arylsilyl group (an aryl silyl group preferably having 18 to 60 carbon atoms, more preferably 18 to 50 carbon atoms, and still more preferably 18 to 40 carbon atoms, such as triphenylsilyl, diphenyl-1-naphthylsilyl and diphenyl-2-naphthylsilyl groups), an alkylarylsilyl group (an alkylarylsilyl group preferably having 15 to 60 carbon atoms, more preferably 15 to 50 carbon atoms, and still more preferably 15 to 40 carbon atoms, such as dimethylphenylsilyl, diphenylmethylsilyl, diphenyl-1-naphthylsilyl and diphenyl-2-naphthylsilyl groups) or an aromatic heterocyclic group-substituted silyl group (an aromatic heterocyclic group-substituted silyl group preferably having 3 to 60 carbon atoms, more preferably 3 to 50 carbon atoms, and still more preferably 3 to 40 carbon atoms, such as tripyridylsilyl and diphenylpyridylsilyl groups), more preferably an arylsilyl group, still more preferably an arylsilyl group having 18 to 60 carbon atoms, and most preferably a triphenylsilyl group that may have at least one substituent.

The aromatic group represented by Y may be an aromatic hydrocarbon group or an aromatic heterocyclic group. The aromatic hydrocarbon group represented by Y preferably has 6 to 30 carbon atoms, more preferably 6 to 20 carbon atoms, and still more preferably 6 to 12 carbon atoms. Examples thereof include phenyl, 4-methyl-phenyl, 4-cyano-phenyl, 1-naphthyl, 2-naphthyl, 1-anthranil, 1-phenanthryl and 1-pyrenyl groups.

The aromatic heterocyclic group represented by Y preferably has 1 to 30 carbon atoms, more preferably 1 to 20 carbon, and still more preferably 1 to 12 carbon atoms. Examples of each of the at least one hetero atom contained in the aromatic heterocyclic group include a nitrogen atom, an oxygen atom and a sulfur atom. Specific examples of the aromatic heterocyclic group represented by Y include imidazolyl, pyridyl, quinolyl, quinoxalyl, furyl, thienyl, pyrazolyl, benzoxazolyl, benzimidazolyl, benzthiazolyl, carbazolyl and azepinyl groups.

The silyl group or aromatic group represented by Y may have at least one substituent. Examples of the substituent include alkyl groups (those preferably having 1 to 30 carbon atoms, more preferably 1 to 20 carbon atoms, and still more preferably 1 to 10 carbon atoms, such as methyl, ethyl, iso-propyl, tert-butyl, n-octyl, n-decyl, n-hexadecyl, cyclopropyl, cyclopentyl and cyclohexyl groups), alkenyl groups (those preferably having 2 to 30 carbon atoms, more preferably 2 to 20 carbon atoms, and still more preferably 2 to 10 carbon atoms, such as vinyl, allyl, 2-butenyl and 3-pentenyl groups), alkynyl groups (those preferably having 2 to 30 carbon atoms, more preferably 2 to 20 carbon atoms, and still more preferably 2 to 10 carbon atoms, such as propargyl and 3-pentynyl groups), aryl groups (those preferably having 6 to 30 carbon atoms, more preferably 6 to 20 carbon atoms, and still more preferably 6 to 12 carbon atoms, such as phenyl, p-methylphenyl, naphthyl and anthranil groups), amino groups (those preferably having 0 to 30 carbon atoms, more preferably 0 to 20 carbon atoms, and still more preferably 0 to 10 carbon atoms, such as amino, methylamino, dimethylamino, diethylamino, dibenzylamino, diphenylamino and ditolylamino groups), alkoxy groups (those preferably having 1 to 30 carbon atoms, more preferably 1 to 20 carbon atoms, and still more preferably 1 to 10 carbon atoms, such as methoxy, ethoxy, butoxy and 2-ethylhexyloxy groups), aryloxy groups (those preferably having 6 to 30 carbon atoms, more preferably 6 to 20 carbon atoms, and still more preferably 6 to 12 carbon atoms, such as phenyloxy, 1-naphthyloxy and 2-naphthyloxy groups), heterocyclic oxy groups (those preferably having 1 to 30 carbon atoms, more preferably 1 to 20 carbon atoms, and still more preferably 1 to 12 carbon atoms, such as pyridyloxy, pyrazyloxy, pyrimidyloxy and quinolyloxy groups), acyl groups (those preferably having 1 to 30 carbon atoms, more preferably 1 to 20 carbon atoms, and still more preferably 1 to 12 carbon atoms, such as acetyl, benzoyl, formyl and pivaloyl groups), alkoxycarbonyl groups (those preferably having 2 to 30 carbon atoms, more preferably 2 to 20 carbon atoms, and still more preferably 2 to 12 carbon atoms, such as methoxycarbonyl and ethoxycarbonyl groups), aryloxycarbonyl groups (those preferably having 7 to 30 carbon atoms, more preferably 7 to 20 carbon atoms, and still more preferably 7 to 12 carbon atoms, such as a phenyloxycarbonyl group), acyloxy groups (those preferably having 2 to 30 carbon atoms, more preferably 2 to 20 carbon atoms, and still more preferably 2 to 10 carbon atoms, such as acetoxy and benzoyloxy groups), acylamino groups (those preferably having 2 to 30 carbon atoms, more preferably 2 to 20 carbon atoms, and still more preferably 2 to 10 carbon atoms, such as acetylamino and benzoylamino groups), alkoxycarbonylamino groups (those preferably having 2 to 30 carbon atoms, more preferably 2 to 20 carbon atoms, and still more preferably 2 to 12 carbon atoms, such as a methoxycarbonylamino group), aryloxycarbonylamino groups (those preferably having 7 to 30 carbon atoms, more preferably 7 to 20 carbon atoms, and still more preferably 7 to 12 carbon atoms, such as a phenyloxycarbonylamino group), sulfonylamino groups (those preferably having 1 to 30 carbon atoms, more preferably 1 to 20 carbon atoms, and still more preferably 1 to 12 carbon atoms, such as methanesulfonylamino and benzenesulfonylamino groups), sulfamoyl groups (those preferably having 0 to 30 carbon atoms, more preferably 0 to 20 carbon atoms, and still more preferably 0 to 12 carbon atoms, such as sulfamoyl, methylsulfamoyl, dimethylsulfamoyl and phenylsulfamoyl groups), carbamoyl groups (those preferably having 1 to 30 carbon atoms, more preferably 1 to 20 carbon atoms, and still more preferably 1 to 12 carbon atoms, such as carbamoyl, methylcarbamoyl, diethylcarbamoyl and phenylcarbamoyl groups), alkylthio groups (those preferably having 1 to 30 carbon atoms, more preferably 1 to 20 carbon atoms, and still more preferably 1 to 12 carbon atoms, such as methylthio and ethylthio groups), arylthio groups (those preferably having 6 to 30 carbon atoms, more preferably 6 to 20 carbon atoms, and still more preferably 6 to 12 carbon atoms, such as a phenylthio group), heterocyclic thio groups (those preferably having 1 to 30 carbon atoms, more preferably 1 to 20 carbon atoms, and still more preferably 1 to 12 carbon atoms, such as pyridylthio, 2-benzimidazolylthio, 2-benzoxazolylthio and 2-benzthiazolylthio groups), sulfonyl groups (those preferably having 1 to 30 carbon atoms, more preferably 1 to 20 carbon atoms, and still more preferably 1 to 12 carbon atoms, such as mesyl and tosyl groups), sulfinyl groups (those preferably having 1 to 30 carbon atoms, more preferably 1 to 20 carbon atoms, and still more preferably 1 to 12 carbon atoms, such as methanesulfinyl and benzenesulfinyl groups), ureido groups (those preferably having 1 to 30 carbon atoms, more preferably 1 to 20 carbon atoms, and still more preferably 1 to 12 carbon atoms, such as ureido, methylureido and phenylureido groups), phosphoric acid amide groups (those preferably having 1 to 30 carbon atoms, more preferably 1 to 20 carbon atoms, and still more preferably 1 to 12 carbon atoms, such as diethylphosphoric acid amide and phenylphosphoric acid amide groups), a hydroxy group, a mercapto group, halogen atoms (such as a fluorine atom, a chlorine atom, a bromine atom, and an iodine atom), a cyano group, a sulfo group, a carboxyl group, a nitro group, a hydroxamic group, a sulfino group, a hydrazino group, an imino group, heterocyclic groups (those preferably having 1 to 30 carbon atoms, and more preferably 1 to 12 carbon atoms, and having at least one hetero atom such as nitrogen, oxygen and sulfur atoms, and specific examples thereof including imidazolyl, pyridyl, quinolyl, furyl, thienyl, piperidyl, morpholino, benzoxazolyl, benzimidazolyl, benzthiazolyl, carbazolyl, and azepinyl groups), silyl groups (those preferably having 3 to 40 carbon atoms, more preferably 3 to 30 carbon atoms, and still more preferably 3 to 24 carbon atoms, such as trimethylsilyl, and triphenylsilyl groups), silyloxy groups (those preferably having 3 to 40 carbon atoms, more preferably 3 to 30 carbon atoms, and still more preferably 3 to 24 carbon atoms, such as trimethylsilyloxy and triphenylsilyloxy groups). These substituents may have at least one substitutent. In addition, at least two of these substituents may bond to each other to form a ring.

Y is preferably an aromatic group, more preferably an aromatic hydrocarbon group, and still more preferably a phenyl group or naphthyl group that may have at least one substituent.

Specific examples of the compound represented by formula (C) in the invention are shown below, but the invention is not limited by these compound. 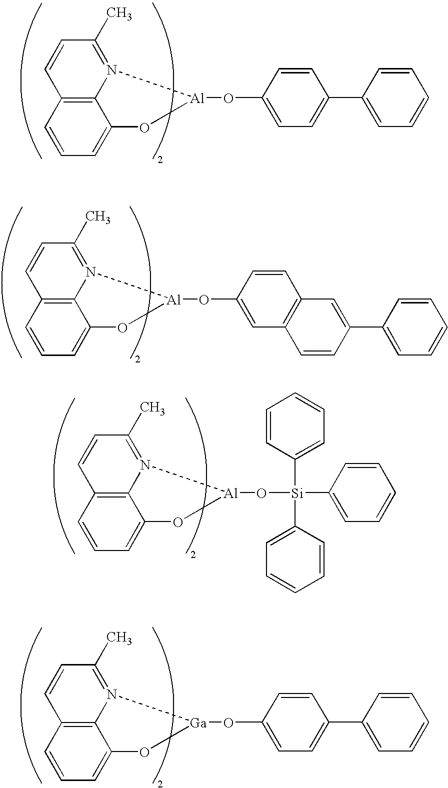
Protective Layer

The whole of the organic EL element of the invention may be protected by a protective layer.

The material(s) contained in the protective layer has the function of inhibiting substances that promote deterioration of the element such as moisture or oxygen from entering the element.

Specific examples thereof include metals such as In, Sn, Pb, Au, Cu, Ag, Al, Ti, and Ni; metal oxides such as MgO, SiO, SiO₂, Al₂O₃, GeO, NiO, CaO, BaO, Fe₂O₃, Y₂O₃, and TiO₂; metal nitrides such as SiNₓ, and SiNₓO_{y}; metal fluorides such as MgF₂, LiF, AlF₃, and CaF₂; polyethylene, polypropylene, polymethyl methacrylate, polyimide, polyurea, polytetrafluoroethylene, polychlorotrifluoroethylene, polydichlorodifluoroethylene, chlorotrifluoroethylene/dichlorodifluoroethylene copolymer, copolymers obtained by copolymerization of a monomer mixture including tetrafluoroethylene and at least one comonomer, fluorine-containing copolymers having at least one cyclic structure in the copolymer main chain, moisture-absorbing materials having a water absorption coefficient of 1% or more, and moisture-resistant materials having a water absorption coefficient of 0.1% or less.

A method for forming the protective layer is not particularly limited, and is, for example, a vacuum deposition method, a sputtering method, a reactive sputtering method, a molecular beam epitaxy (MBE) method, a cluster ion beam method, an ion plating method, a plasma polymerization method (radiofrequency excitation ion plating method), a plasma CVD method, a laser CVD method, a thermal CVD method, a gas source CVD method, a coating method, a printing method, or a transfer method.

Sealing

The organic electroluminescent element of the invention may be contained in a sealing vessel which is sealed.

A moisture absorbent or an inactive liquid may be contained in the space formed between the sealing vessel and the luminescent element. The type of the moisture absorbent is not particularly limited. Examples thereof include barium oxide, sodium oxide, potassium oxide, calcium oxide, sodium sulfate, calcium sulfate, magnesium sulfate, phosphorous pentaoxide, calcium chloride, magnesium chloride, copper chloride, cesium fluoride, niobium fluoride, calcium bromide, vanadium bromide, molecular sieve, zeolite, and magnesium oxide. The type of the inactive liquid is not particularly limited. Examples thereof include paraffins, liquid paraffins, fluorinated solvents such as perfluoroalkanes, perfluoroamines and perfluoroethers, chlorinated solvents, and silicone oils.

The organic electroluminescent element of the invention can emit light, when direct voltage, which is typically 2 volts to 15 volts, and, if necessary, may be combined with an AC component, or a DC current is impressed between the anode and the cathode.

The organic electroluminescent element of the invention can be driven by any of driving methods described in JP-A Nos. H02-148687, H06-301355, H05-29080, H07-134558, H08-234685 and H08-241047, Japanese Patent No. 2784615, and U.S. Pat. Nos. 5,828,429 and 6,023,308.

The driving durability of the organic electroluminescent element of the invention can be evaluated in terms of the intensity half-life of the element at a specific intensity. The driving durability can be measured by, for example, the following method. The organic EL element is subjected to a continuous driving test. In this test, a direct voltage is applied to the organic EL element with a source measure unit (2400 model manufactured by Keithley Instruments Inc.) so as to cause the element to emit light. Here, the initial intensity (luminance) is adjusted at 2000 cd/m². The duration from the starting of the test until a time when the intensity has just reached 1000 cd/m² is regarded as the intensity half-life T(½). In Examples of the specification, the intensity half-life of the organic electroluminescent element of the invention is compared with that of each of conventional luminescent elements.

In addition, the intensity-current-voltage characteristic of the element is measured simultaneously with the measurement of the driving durability, and is used as the luminescence efficiency (cd/A) of the element, which is one of luminescence characteristics.

The organic EL element of the invention can be preferably used in display elements, display devices, backlights, electrophotographic devices, illumination light sources, recording light sources, exposure light sources, reading light sources, indicators, signboards, interiors and optical communications.

### EXAMPLES

The invention will be described, while referring to the following examples, which are not intended to limit the invention.

### Comparative Example 1

An ITO thin film having a thickness of 0.2 μm and serving as a transparent anode was formed on a glass substrate having a surface area of 2.5 cm² and a thickness of 0.5 mm by using an ITO target containing 95% by mass of In₂O₃ and a DC magnetron sputtering method. In this method, the substrate temperature was 100° C., and the oxygen pressure was 1×10⁻³ Pa. The surface resistance of the ITO thin film was 10 Ω/sq.

Then, the substrate on which the transparent anode had been formed was placed in a washing vessel, washed with isopropyl alcohol (IPA), taken out of the washing vessel, and subjected to UV-ozone treatment for 30 minutes. Thereafter, copper phthalocyanine (CuPC) was deposited on the transparent anode by vacuum deposition at a rate of 0.5 nm/second to provide a hole-injecting layer having a thickness of 10 nm.

N,N′-di-α-naphthyl-N,N′-diphenylbenzidine (α-NPD) was deposited on the hole-injecting layer by vacuum deposition at a rate of 0.5 nm/second to provide a hole transport layer having a thickness of 30 nm. CBP serving as a host material and Ir(ppy)₃ serving as a phosphorescent material were co-deposited on the hole transport layer at a ratio of 100 to 5 by vacuum deposition to obtain a luminescent layer having a thickness of 30 nm.

BAlq was deposited on the luminescent layer by vacuum deposition at a rate of 0.5 nm/second to form an electron transport layer having a thickness of 10 nm, and Alq₃ was deposited on the layer by vacuum deposition at a rate of 0.2 nm/second. Thus, an electron-injecting layer having a thickness of 40 nm was provided.

A patterned mask with an opening having an area of 2 mm×2 mm was placed on the electron-injecting layer, and lithium fluoride was deposited in the opening by vacuum deposition to form a layer having a thickness of 1 nm on the electron-injecting layer. Subsequently, aluminum was deposited on the lithium fluoride layer by vacuum deposition to provide a cathode having a thickness of 0.1 μm. Thus, a luminescence laminate was obtained.

The luminescence laminate was placed in a glove box filled with argon gas and put in a sealing can made of stainless steel and containing a drying agent and the sealing can was sealed with an ultraviolet curable adhesive (XNR5516HV manufactured by Nagase-Chiba Co.). Thus, a luminescent element of Comparative Example 1 was obtained.

The operations from the deposition of copper phthalocyanine to sealing were conducted in a vacuum or under a nitrogen atmosphere, and the element was fabricated without exposure to air. 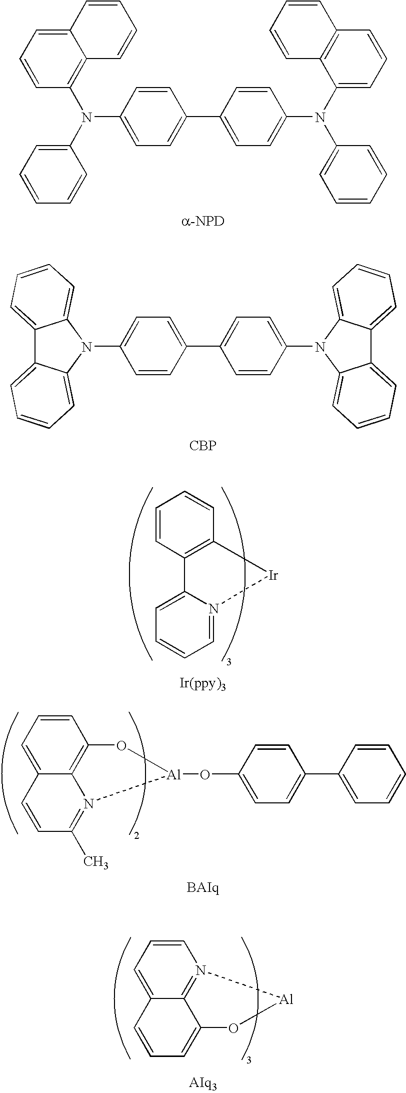
Evaluation

The electron affinity (Ea) of each of the electron transport material in the electron injection promoting layer and the luminescent material and the host material in the luminescent layer was calculated from the band gap and the ionization potential (IP) of each of these materials. Here, the band gap was obtained by forming a monolayer film of the material, measuring the absorption spectrum of the monolayer film, and calculating the band gap from the absorption peak having the longest wavelength. The ionization potential (Ip) of each material was measured with an ultraviolet photoelectronic analyser (AC-1 manufactured by Riken Keiki Co., Ltd.). The results are shown in Table 1.

The driving durability and the luminescence efficiency of the luminescent element were measured by the following methods.

—Driving Durability Test—

The luminescent element was subjected to a continuous driving test at a current density of 10 mA/cm², and the duration from the starting of the test until a time when the measured intensity became the half of the initial intensity was regarded as the intensity half-life T (½).

—Luminescence Efficiency—

A voltage was applied to the luminescent element, and the intensity-current-voltage characteristic of the element was measured, and the luminescence efficiency (cd/A) was calculated from the characteristic.

### Comparative Example 2

A luminescent element of Comparative Example 2 was produced and evaluated in the same manner as in Comparative Example 1, except that the following compound (a) was further deposited by vacuum deposition at a rate of 0.05 nm/second to form an electron injection promoting layer disposed between the luminescent layer and the electron transport layer and having a thickness of 10 nm. The results are shown in Table 1.

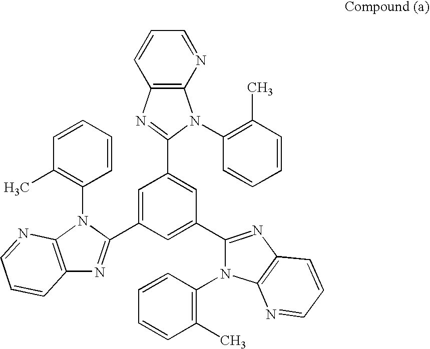

Comparative Example 3

A luminescent element of Comparative Example 3 was produced and evaluated in the same manner as in Comparative Example 2, except that α-NPD, rather than compound (a), was deposited by vacuum deposition at a rate of 0.05 nm/second to form an electron injection promoting layer having a thickness of 1 nm. The results are shown in Table 1.

### Example 1

A luminescent element of Example 1 was produced and evaluated in the same manner as in Comparative Example 2, except that the electron injection promoting layer was replaced with another electron injection promoting layer formed by vacuum-depositing compound (a) at a rate of 0.02 nm/second and having a thickness of 1 nm, and except that the electron transport layer was not formed, and except that the electron-injecting layer was replaced with another electron-injecting layer formed by vacuum-depositing Alq³ at a rate of 0.2 nm/second and having a thickness of 50 nm. The results are shown in Table 1.

### Example 2

A luminescent element of Example 2 was produced and evaluated in the same manner as in Comparative Example 2, except that the thickness of the electron injection promoting layer made of compound (a) was changed to 0.5 nm. The results are shown in Table 1.

### Example 3

A luminescent element of Example 3 was produced and evaluated in the same manner as in Comparative Example 2, except that the thickness of the electron injection promoting layer made of compound (a) was changed to 1 nm. The results are shown in Table 1.

### Example 4

A luminescent element of Example 4 was produced and evaluated in the same manner as in Comparative Example 2, except that the thickness of the electron injection promoting layer made of compound (a) was changed to 3 nm. The results are shown in Table 1.

TABLE 1

| | | Comp. Ex. 1 | Comp. Ex. 2 | Comp. Ex. 3 | Example 1 | Example 2 | Example 3 | Example 4 |
|---|---|---|---|---|---|---|---|---|
| Material of hole-injecting layer/that of hole | | CuPc/ | CuPc/ | CuPc/ | CuPc/ | CuPc/ | CuPc/ | CuPc/ |
| transport layer | | α-NPD | α-NPD | α-NPD | α-NPD | α-NPD | α-NPD | α-NPD |
| Luminescent layer | Host material | CBP | CBP | CBP | CBP | CBP | CBP | CBP |
| | Luminescent | Ir(ppy)₃ | Ir(ppy)₃ | Ir(ppy)₃ | Ir(ppy)₃ | Ir(ppy)₃ | Ir(ppy)₃ | Ir(ppy)₃ |
| | material | | | | | | | |
| Electron injection | Electron transport | — | Compound | α-NPD | Compound | Compound | Compound | Compound |
| promoting layer | material | | (a) | | (a) | (a) | (a) | (a) |

| | | | | | | | |
|---|---|---|---|---|---|---|---|
| Material of Electron transport layer | Balq | Balq | Balq | — | Balq | Balq | Balq |
| Thickness of electron injection promoting | — | 10 | 1 | 1 | 0.5 | 1 | 3 |
| layer (nm) | | | | | | | |
| Ea (ET): Ea (eV) of electron transport | — | 3.6 | 2.4 | 3.6 | 3.6 | 3.6 | 3.6 |
| material in electron injection promoting layer | | | | | | | |
| Ea (EM): Ea (eV) of luminescent material in | 2.8 | 2.8 | 2.8 | 2.8 | 2.8 | 2.8 | 2.8 |
| luminescent layer | | | | | | | |
| Ea (H): Ea (eV) of host material in | 2.7 | 2.7 | 2.7 | 2.7 | 2.7 | 2.7 | 2.7 |
| luminescent layer | | | | | | | |
| Durability *1 (hour) | 1100 | 350 | 630 | 1100 | 1500 | 1400 | 1100 |
| Luminescence efficiency (cd/A) at 10 mA/ | 27 | 36 | 25 | 34 | 35 | 34 | 33 |
| cm² | | | | | | | |

Note)
*1 Duration from start of test until time when measured intensity became half of initial intensity 2000 cd/cm²

As is evident from Table 1, the element of Comparative Example 3 has improved luminescence efficiency, but significantly shortened intensity half-life in comparison with the element of Comparative Example 1. The element of Comparative Example 2 has much shorter intensity half-life than the element of Comparative Example 1. These results show that, even when an electron injection promoting layer having a thickness and an electron affinity of the electron transport material contained therein out of the respective ranges recited in the invention is formed, shortened intensity half-life and decreased luminescence efficiency are obtained.

On the other hand, as is evident from the examples, luminescent elements having a thickness and an electron affinity of the electron transport material contained therein within the respective ranges show excellent luminescence efficiency and lengthened intensity half-life.

What is claimed is:

1. An organic electroluminescent element comprising a cathode, an electron injection promoting layer, a luminescent layer, and an anode in that order, wherein the luminescent layer is adjacent to the electron injection promoting layer and contains a luminescent material, the electron injection promoting layer contains an electron transport material and has a thickness of 3 nm or less, and the electron affinity of the electron transport material is equal to or higher than the electron affinity of the luminescent material.

2. The organic electroluminescent element of claim 1, wherein the luminescent layer contains a host material, and the electron affinity of the electron transport material is equal to or higher than the electron affinity of the host material.

3. The organic electroluminescent element of claim 1, wherein the luminescent material is a phosphorescent material.

4. The organic electroluminescent element of claim 2, wherein the luminescent material is a phosphorescent material.

5. The organic electroluminescent element of claim 1, wherein the electron affinity of the electron transport material contained in the electron injection promoting layer is 2.7 eV or higher.

6. The organic electroluminescent element of claim 2, wherein the electron affinity of the electron transport material contained in the electron injection promoting layer is 2.7 eV or higher.

7. The organic electroluminescent element of claim 1, wherein the film thickness of the electron injection promoting layer is from 0.1 to 2 nm.

8. The organic electroluminescent element of claim 2, wherein the film thickness of the electron injection promoting layer is from 0.1 to 2 nm.

9. The organic electroluminescent element of claim 1, wherein the electron transport material contained in the electron injection promoting layer is represented by the following formula (A-1) or (B-1): 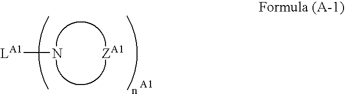
wherein formula (A-1), Z^{A1} represents an atomic group required for formation of a nitrogen-containing heterocyclic group, L^{A1} represents a linking group, and n^{A1} represents an integer of 2 or more: 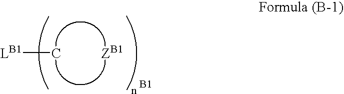
wherein formula (B-1), Z^{B1} represents an atomic group required for formation of an aromatic hydrocarbon ring or a heterocyclic group, L^{B1} represents a linking group, and n^{B1} represents an integer of 2 or more.

10. The organic electroluminescent element of claim 1, wherein the electron transport material contained in the electron injection promoting layer is represented by the following formula (A-1) or (B-1): 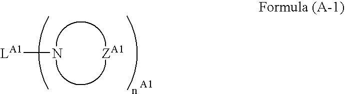
wherein formula (A-1), Z^{A1} represents an atomic group required for formation of a nitrogen-containing heterocyclic group, L^{A1} represents a linking group, and n^{A1} represents an integer of 2 or more, and 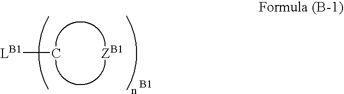
wherein formula (B-1), Z^{B1} represents an atomic group required for formation of an aromatic hydrocarbon ring or a heterocyclic group, L^{B1} represents a linking group, and n^{B1} represents an integer of 2 or more.

11. The organic electroluminescent element of claim 1, wherein the electron transport material contained in the electron injection promoting layer contains three or more nitrogen atoms.

12. The organic electroluminescent element of claim 2, wherein the electron transport material contained in the electron injection promoting layer contains three or more nitrogen atoms.

13. The organic electroluminescent element of claim 2, wherein the host material has a carbazole group.

14. The organic electroluminescent element of claim 3, wherein the host material has a carbazole group.

15. The organic electroluminescent element of claim 1, wherein an electron transport layer containing a compound represented by the following formula (C) is provided between the cathode and the electron injection promoting layer and adjacent to the electron injection promoting layer: 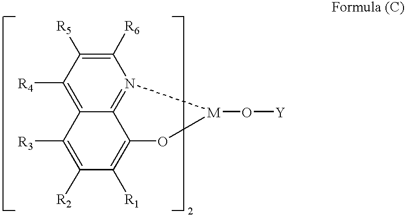
wherein at least one of R₁ to R₆ represents a substitute, and the remaining represent a hydrogen atom, M represents aluminum, gallium or indium, and Y represents an aromatic group or silyl group that may have a substituent.

16. The organic electroluminescent element of claim 2, wherein an electron transport layer containing a compound represented by the following formula (C) is provided between the cathode and the electron injection promoting layer and adjacent to the electron injection promoting layer: 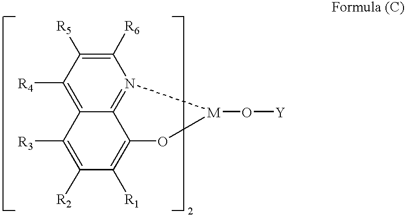
wherein at least one of R₁ to R₆ represents a substitute, and the remaining represent a hydrogen atom, M represents aluminum, gallium or indium, and Y represents an aromatic group or silyl group that may have a substituent.
